(19) United States
(12) Patent Application Publication
(10) Pub. No.: US 2011/0174375 A1
(43) Pub. Date: Jul. 21, 2011

(54) Solar module containing an encapsulated solar cell and method of providing an electrical connection through the encapsulation to deliver electrical energy

(76) Inventors: Kurt Nattermann, Ockenheim (DE); Dieter Franke, BL VAALS (NL); Ingo Schwirtlich, Miltenberg (DE)

(21) Appl. No.: 13/007,686

(22) Filed: Jan. 17, 2011

(30) Foreign Application Priority Data
Jan. 19, 2010 (DE) 10 2010 001 016.2

(51) Int. Cl. H01L 31/0224; C03B 23/20

(52) U.S. Cl. 136/259; 65/36

(57) ABSTRACT

The solar module for converting radiation energy, in particular sunlight, into electrical energy, includes a solar cell (12) that converts radiation energy into electrical energy, an electrical conductor (24) to conduct the electrical energy, an encapsulation (14) encasing the solar cell (12) to protect the solar cell (12), which includes one or more panes (16) of glass to protect and stabilize the solar cell (12) and a layer (22) of embedment material into which the solar cell (12) is laminated or cast, and a body (26) fused into the pane (16) of glass to conduct the electrical energy or to pass an electrical conductor (24) through the pane of glass (16). Furthermore, a method for fusing the body (26) into the one or more panes (16) of glass of the solar module is also described.

### CROSS-REFERENCE

The invention disclosed and claimed herein below is also described in German Patent Application DE 10 2010 001 016.2, filed on Jan. 19, 2010, in Germany, whose subject matter is incorporated herein by explicit reference thereto. The aforesaid German Patent Application provides the basis for a claim of priority of invention for the invention claimed herein below under 35 U.S.C. 119 (a) to (d).

### BACKGROUND OF THE INVENTION

1. The Field of the Invention

The present invention relates to a solar module for converting radiation energy, in particular sunlight, into electrical energy, which comprises a solar cell to convert radiation energy into electrical energy, an electrical conductor to conduct the electrical energy and an encapsulation encasing the solar cell to protect the solar cell, wherein the encapsulation comprises one or more panes of glass to protect and stabilize the solar cell and a layer of embedment material into which the solar cell is laminated or cast. In addition, the invention relates to a method for producing a respective solar module.

2. Description of the Related Art

To be able to operate solar cells as efficiently as possible, they must be exposed to sunlight as long as possible. Thus they must be installed outdoors and not in an area that is in the shadows, for example by buildings or trees. As a result, they are exposed to a number of extraneous influences, such as particles of dirt, hail, temperature fluctuations and corrosive media. Furthermore, the solar cells can be damaged during installation or preventive maintenance. Therefore, they are encapsulated to protect them from these influences and to guarantee electrical safety. Besides the one or more panes of glass which are arranged in the direction of the incident rays in front of the solar cell and the layer of embedment material, an essential component of an encapsulation is a film on the backside of the solar cell, which can alternatively be replaced by a further pane of glass. The embedment material is a transparent plastic, such as ethylene vinyl acetate (EVA) or silicone rubber.

The solar cells and the encapsulation are a part of the solar module, which in addition normally comprises an attachment jack as well as frames, for example made of aluminium, steel or fiber-reinforced plastic, to protect the pane of glass during transport, handling and installation and to fix and support the solar module.

The panes of glass, which are used in a solar module, are normally made of soda glass and have a thickness of several millimeters to provide the solar module with the required rigidity. The panes of glass may have an antireflection coating to avoid reflection of the sun in the solar modules, which may cause irritations, for example for aircraft.

In most cases, silicon in two different forms is used as a starting material for solar cells, on the one hand crystalline silicon (c-Si) and on the other hand amorphous silicon (a-Si).

The most productive form is monocrystalline silicon, which has been “pulled” according to the Czochralski method and which provides efficiency factors of 12 to 15%. However, in this case the highest purity is required which results in high production costs. Anyway, this material is needed for transistors, integrated circuits and similar uses. However polycrystalline silicon for solar cells, which can be produced in a much cheaper way, is also suitable. Polycrystalline silicon can be cast into blocks and can provide efficiency factors of 10 to 13%.

Normally, monocrystalline and polycrystalline solar cells have a square shape with dimensions of ca. 15×15 cm. They are sawed off from pulled or cast blocks of silicon using special saws. Monocrystalline solar cells of silicon can be identified by their uniform and smooth surface as well as their broken edges for which the production method can be blamed. They are sawed out of round disks, the round shape of which is again a result of the blocks which have been pulled according to the Czochralski method.

However, polycrystalline solar cells have a square shape like the cast blocks from which they are sawed off. They have an irregular surface on which the crystallites having diameters of a few millimeters up to a few centimeters can be clearly seen.

Normally, the technically possible thickness of these sawed off or sawed out disks is ca. 0.2 mm. The critical factor that determines the amount of electrical energy, which can be generated from incident radiation energy is the area of the solar cell and not its thickness, so that it is advantageous to produce thinner disks, which decreases production costs, because more disks can be produced from the same block of silicon.

Amorphous silicon has no crystalline structure but consists of randomly arranged silicon atoms which are vapor deposited onto glass or another substrate. Amorphous silicon has high absorption capacity and therefore can be used for solar cells having particularly low layer thicknesses. In this case, the normal layer thicknesses are smaller by a factor of 100 than in the case of crystalline silicon. This compensates the low efficiency factor of about 6 to 8%, which is caused by its defects and results in the fact that from an economical point of view amorphous silicon is an interesting material for applications in the solar industry.

In the solar module electrical conductors must be installed to connect electrical lines to the solar cells and to be able to collect the electrical energy generated by them. For that purpose it is known for example from DE 102 25 140 A1 to drill holes into the pane of glass at special sites on the backside of the solar module. In the case that the backside is formed by a film the holes are not drilled, but punched into the film. The electrical conductor can be guided out of the solar module through these holes and can be connected to external circuits.

For example, the conductors can be provided in the form of solder bars with which the solar cells or whole solar modules are connected electrically with each other. Normally, most often 8 to 12 serially connected solar cells are combined in one string or array. Furthermore, the solder bars are normally installed in a U-shaped arrangement, so that two adjacent strings can be combined to one unit. Then each string is connected with a diode, which is a reverse-biasing pole in the normal operational status (solar cell provides electricity). If a solar cell does not provide electricity due to shadowing or a defect, the now reverse-biasing diodes would put a string consisting of several solar cells connected in series out of operation. When the voltage of the serially connected properly functioning and irradiated solar cells exceeds the blocking voltage of the not irradiated solar cell, this one indeed can be destroyed. This is prevented by the diodes. Therefore, also in this case a string can provide electricity, even though in a smaller amount.

In DE 761 322 an electrode system is arranged in a flask which stands on a pod of molded glass. In this case two electrical conductors pass through the pod of molded glass. Here the passage site is sealed with glass solder. DE 761 322 does not relate to solar modules.

DE 30 47 399 A1 relates to a method for mechanically and electrically connecting encapsulated solar cells with external attachment lines. In this case the important feature is the provision of a conducting connection through the encapsulation material so that the electrical energy which is provided by the solar cells can be transmitted into a cable via an attachment element. The invention disclosed in DE 30 47 399 A1 does not relate to a lead-through through panes of glass.

In the event that the backside of the solar module is formed by a pane of glass, the drilled holes for passing through the electrical conductors have the disadvantage that they weaken the pane of glass, which results in lower strength and carrying capacity. A further disadvantage of this design of the backside comprising a pane of glass or also a film is that the holes admit environmental media, such as dust particles, humidity and corrosive gases, e.g. ammonia in the case of livestock farming facilities, since the holes are not sealed around the conductors. These environmental media may damage the solar cells and may cause a considerable decrease in their economic service life.

### SUMMARY OF THE INVENTION

Therefore, the object of the present invention is the development of solar modules of the above-mentioned type, so that the electrical energy provided by the solar cells can be delivered from the solar module in a mechanically secure and permanently connected way without noticeably complicating the production method of the solar module in question.

This object is attained by providing a body, which is fused into the one or more panes of glass to conduct the electrical energy through the one or more pane of glass or to pass or guide an electrical conductor through the one or more panes of glass. Indeed, the electricity normally is delivered or conducted from the backside of the solar module. However it is also possible to deliver the electricity from the front side of the solar module. Therefore, the body may be fused into a pane of glass on the front side, a pane of glass on the backside or also in panes of glass on the front and backside. Because the body is fused into the one or more panes of glass, it is guaranteed that the area of contact between the pane or panes of glass and the body is permanently sealed so that no media, in particular liquids and corrosive gases, can penetrate into the solar module. Therefore, the solar cells are protected from these media so that their economic service life can be extended. Furthermore, the body forms an interconnection with the one or more panes of glass, since it is fused into the one or more panes of glass, so that they are not mechanically weakened by drilled holes.

The strength and the carrying capacity of the one or more panes of glass are not reduced so that overall the solar module can bear greater mechanical loads. Furthermore, the one or more panes of glass may be tempered which then is used for fixing the body according to the present invention. This tempered state is not lost by the fusion of the body into the pane of glass according to the present invention.

Preferably, the body is configured as an electrically conductive pin, which is conductively connected with the electrical conductor. Thus the body becomes a part of the delivery means for the electrical energy produced by the solar module. This design is particularly simple with respect to its manufacturing technique and therefore can be realized in an inexpensive way. The electrical conductors only have to be fixed on both sides of the body, for example by soldering. Thus the body must consist of an electrically conductive material, such as metal, which however is a widespread material for pins so that this limitation does not result in any technical disadvantage.

In a preferred design the pin is provided as a cylindrical pin, a tapered dowel pin or a bolt with a head. With these designs standard parts can be used which are produced in high quantity and thus are available very cheaply. Furthermore, the tapered dowel pins and the bolts with the head have the additional advantage that their position at least in one direction is widely predetermined so that they can more easily be positioned at the desired site during the fusion process. In addition, the risk of getting out of place during the fusion process is reduced.

In an advantageous design of the present invention the body has a through-hole for passing the electrical conductor through the body and through the pane of glass. Here, the electrical conductor must not be connected with the body in an electrically conductive way, so that electrical current can continuously be passed out of the solar module to adjacent circuits by means of the electrical conductor.

In a preferred embodiment of the solar module according to the present invention the body is provided with a thread, i.e. a hole that is threaded, into which a screw can be screwed in so as to connect the electrical conductor with the body in an electrically conductive way. In this way, an electrically conductive connection can be produced in a simple manner, but at the same time this connection is extremely solid, for example in comparison with soldered joints. Preferably, the thread is arranged in such a manner that the screw can be screwed into the thread on the front side of the solar module, thus from the direction of the incident rays. This has the advantage that the screw joint is well accessible and visible. Thus, the installation can be simplified and errors in the wiring of the solar module can be identified and repaired more easily.

Preferably, the solar module according to the present invention has a further encapsulation to protect the electrical conductor and to secure the screw. Here, the encapsulation material of the further encapsulation may be equivalent to that of the encapsulation. In this case, the further encapsulation is designed such that it encompasses the screw and partially the electrical conductor. On the one hand the body, the thread and the screw can be protected from extraneous influences, in particular influences of weather, and on the other hand the electrical conductor can also be protected from mechanical influences, such as tensile loading, when the further encapsulation is designed accordingly. Furthermore, the loosening of the screw can be prevented.

Preferably, the body consists of a non-conducting material and has a through-hole for passing the electrical conductor through the body and through the one or more panes of glass. With this design there is no limitation with respect to the kind of material from which the body is made. Here, the materials may, for example, be selected such that their coefficient of thermal expansion can be adjusted to that of the glass. This can advantageously be used in the fusion process to induce targeted tensions in the one or more panes of glass which safely and permanently fix the body in the one or more panes of glass.

A further aspect of the present invention relates to a method for fusing the body into one or more panes of glass of a solar module according to one of the above embodiment examples, wherein the body serves for passing or guiding an electrical conductor through the one or more panes of glass and for conducting the electrical energy through the one or more panes of glass, comprising the following steps:
heating the one or more panes of glass from a first temperature to a second temperature, wherein the second temperature is equal to or greater than the glass transition temperature of the glass in the one or more panes,
passing the body through the one or more panes of glass at the second temperature, and
cooling the one or more panes of glass to a third temperature.

The glass transition or softening temperature T_{G} separates the lower brittle energy-elastic range from the higher soft entropy-elastic range of the glass in question. In this soft range the body can be passed through the one or more panes of glass with relatively low exertion of force without damaging the one or more panes of glass, in particular without forming cracks. The body can be passed through the heated pane or panes of glass by the use of a suitable tool. The second temperature may be much higher than the glass transition temperature, but it is important that it is not too great so that the glass is not permanently modified, for example by unmixing, devitrification or evaporation. Normally, the first temperature is room temperature, but it is also possible to choose another temperature from which the pane or panes of glass is heated to the second temperature. Normally, also the third temperature is room temperature so that the first and third temperatures may be the same, but this is not necessary. It may be advantageous, at first to cool the pane of glass to a temperature which is different from room temperature and then to maintain this temperature for some time, before the pane or panes of glass are allowed to adjust to room temperature.

The method according to the present invention is further developed by heating the pane or panes of glass in a passing area in which the body is passed through the pane or panes of glass. The term “passing area” means an area which encompasses the site at which the body is passed through the pane or panes of glass. Here, an exact a real limitation of the passing area should not be given, since its a real dimensions depend on many factors, such as the glass used and/or the value of the second temperature. However the center of the passing area is preferably located approximately on the longitudinal axis of the body.

Only heating this passing area has the advantage that the whole pane or panes of glass do not need to be heated which is energetically advantageous and facilitates the handling of the pane or panes of glass during the fusion process of the body. The reason for that is that the pane or panes of glass as a whole are still solid and are only soft and thus malleable in the passing area. The passing area can be heated by a gas flame or a CO₂ laser, wherein the temperature of the pane of glass in the passing area can be measured and controlled for example with the use of a pyrometer, pyranometer or a pyrheliometer. A further advantage of the local heating of the passing area is that the tempered state of the pane of glass is maintained.

In an advantageous further embodiment of the method according to the present invention, in which the pane or panes of glass have two glass faces on opposite sides, both glass faces are heated. From a geometric point of view the panes are bodies which are characterized in that they have two faces oppositely arranged the area of which being much larger than the residual face(s). The same is true of the pane or panes of glass used here. By simultaneously heating both glass faces, on the one hand the heating of the pane or panes of glass or the passing area thereof can be advanced and on the other hand a more uniform temperature profile can be reached within the pane or panes of glass. So the risk is reduced that there are sections of the glass in the passing area having a temperature of lower than the softening temperature which may result in damage of the pane of glass during the passing process of the body.

The method according to the present invention is further developed by a forced cooling of the pane or panes of glass from the second to the third temperature. On the one hand, in this way the production method can be improved, since the time required for cooling is reduced. On the other hand, targeted tensions in the pane or panes of glass in the passing area of the body which has been fused in are induced by the forced cooling, which have an effect on the body and which connect the body with the pane or panes of glass in a firmer and more solid manner. Thus, loosening and optional separation of the body from the pane of glass can widely be prevented.

The method according to the present invention is further developed by the following steps:
heating the body from a first body temperature to a second body temperature,
passing the body at the second body temperature through the pane of glass at the second temperature, and
cooling the body from the second body temperature to a third body temperature.

In this context the term “body temperature” means the temperature of the body which is fused into the pane of glass according to the present invention. There is no relation to the temperature of the human body. The term is used to differentiate from the temperature of the pane of glass.

The second body temperature can be chosen lower than the second temperature of the pane of glass. This is advantageous, when the coefficient of thermal expansion of the material from which the body is manufactured is greater than that of the glass used. During the cooling process the glass is shrunk-fit onto the body so that tensions are induced in the pane or panes of glass which have an effect on the body in the cooled state and fix it in the pane or panes of glass.

On the other hand, the second body temperature can be chosen greater than the second temperature of the pane or panes of glass. This is advantageous, when the coefficient of thermal expansion of the material from which the body is manufactured is lower than that of the glass. During the cooling process the glass is shrunk-fit onto the body so that tensions are induced in the pane or panes of glass which have an effect on the body in the cooled state and fix it in the pane or panes of glass.

In both cases it has to be considered that all dimensions of the body are proportionally changed relative to each other with a change in temperature. Thus for example the diameter of a hole which is created by passing the body through the pane of glass is reduced with the same ratio as the residual dimensions of the pane of glass during a cooling process, wherein tensions can be created which have an effect on the body and fix it in the pane of glass.

Furthermore, the method can further be developed by subjecting the body to a forced cooling from the second to the third body temperature. Also with this measure the production process can be advanced and targeted tensions can be introduced into the pane or panes of glass. The cooling process may be conducted in any suitable way, such as by blowing off with compressed air or by passing the pane of glass through a cooling chamber.

### BRIEF DESCRIPTION OF THE DRAWING

In the following, preferred embodiment examples of the invention are explained in detail in relation to the appended figures.

FIG. 1 is a cross-sectional view through a first embodiment example of a solar module according to the present invention.

FIG. 2 is a cross-sectional view through a second embodiment example of the solar module according to the present invention.

FIG. 3 is a cross-sectional view through a third embodiment example of the solar module according to the present invention.

FIG. 4 is a cross-sectional view through a fourth embodiment example of the solar module according to the present invention.

### DESCRIPTION OF THE PREFERRED EMBODIMENTS

A first embodiment example of a solar module according to the present invention 10 is shown in a cross-sectional view in FIG. 1. The solar module 10 comprises a solar cell 12 which is arranged in an encapsulation 14. For reasons of clarity only one solar cell 12 is shown. However the solar module 10 may comprise any number of solar cells. In this connection 60 or 72 solar cells are often combined in one string consisting of 6×10 or 6×12 solar cells.

In the embodiment example shown in FIG. 1 the encapsulation 14 comprises a pane 16 of glass having a first glass face 18 and a second glass face 20 and a layer 22 of embedment material. The encapsulation 14 may also comprise a further pane 16 of glass or a film. In the example shown the radiation energy impinging on or falling on the solar cell 12 should pass through the pane 16 of glass from the first glass face 18 to the second glass face 20. Accordingly, the solar cell 12 is arranged in direct contact with the second glass face 20 of the pane 16 of glass so that the radiation energy travels as short a distance as possible through the solar module 10 and thus losses are minimized.

The solar cell 12 may consist of any suitable material, for example amorphous or crystalline silicon. On the side of the solar cell 12 which is opposite from the pane 16 of glass an electrical conductor 24 is connected with the solar cell 12 which delivers the electrical energy produced by the solar cell. For example, the electrical conductor 24 may be configured as a solar bar. The electrical conductor 24 has an electrical connection, for example made by soldering, with a body 26′, which is fused into the pane 16 of glass. In the embodiment example shown in FIG. 1 the body 26′ is substantially cubically or cylindrically shaped and has an inner end 28 and an outer end 30. The geometric shape of the body 26′ can be arbitrarily chosen. The body 26′ passes through the pane of glass 16 so that additional conductors may be connected (not shown) to the outer end 30 of the body 26′ to integrate the solar cell or the solar module 10 into an electric circuit.

In the embodiment example shown in FIG. 1 the electrical energy is delivered on the side of the solar module 10 facing the radiation source, typically the sun. Normally, the electrical energy is delivered on the side, which is the far side from the sun. The principle according to the present invention is not limited to a particular side of the solar module 10 and can be arbitrarily used with one side or with the other side or both sides. Furthermore, the solar cell 12 is covered with the layer 22 of encapsulation material on the side which is the far side from the sun. But it is also possible to manufacture the layer 22 with a thickness which corresponds to that of the solar cell 12 so that it is flush with the solar cell 12. In this case, the solar cell 12 would only by encased by the layer 22 of encapsulation material on the facing side.

The body 26′ extends beyond both sides of the pane 16 of glass. But it can also be designed so that it is flush with the glass faces 18, 20 on one or both sides of the pane 16 of glass. In particular in this manner the body 26′ avoids collisions with articles in the vicinity of its outer end 30, which are part of the environment of the solar module 10. Such collisions may result in loosening of the body 26′ or in damage to the pane of glass 16 and thus the solar module 10.

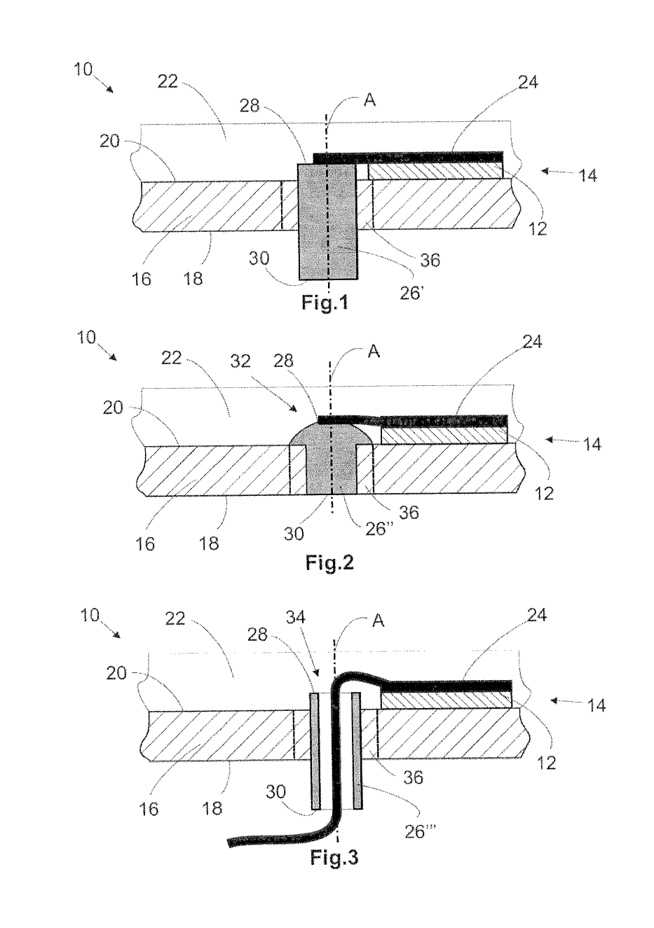

In FIG. 2 a second embodiment example of the solar module 10 according to the present invention is shown. The design is substantially the same as that of the first embodiment example described in FIG. 1. However the body 26″ is designed as a bolt with a head 32 in contrast to the embodiment example shown in FIG. 1. The head 32 serves as a mechanical stop so that the position of the body 26″ with respect to the pane 16 of glass during the fusion process can be determined more easily. In this embodiment example the outer end 30 is flush with the first glass face 18. The electrical conductor 24 is connected at the head 32 with the body 26″.

In the third embodiment example of the solar module 10 according to the present invention shown in FIG. 3 the body 26′″ has a through-hole 34 through which the electrical conductor 24 can be passed. In this case the body 26′″ must not be manufactured of electrically conductive material. In addition, the electrical conductor 24 must not be electrically connected with the body 26′″.

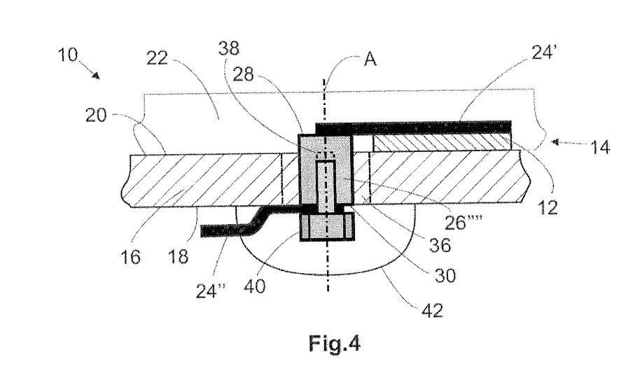

A fourth embodiment example of the solar module 10 according to the present invention is shown in FIG. 4. Here, the body 26″″ has a thread 38 (threaded hole) into which a screw 40 can be screwed in or secured in a direction from the first glass face 18 to the second glass face 20, thus from the front side of the solar module onto which the rays impinge. The electrical conductor 24 is separated into a first section 24′ and a second section 24″, wherein the first section 24′ is arranged inside the encapsulation 14 and is connected with the solar cell 12. The second section 24″ of the electrical conductor 24 may comprise a blade terminal and can be conductively connected with the body 26″″ by a screw 40. Preferably, a further encapsulation 42 is provided to protect and seal the body 26″″, the second section 24″ of the electrical conductor 24 and the electrically conductive connection between the body 26″″ and the second section 24″ of the electrical conductor 24 from extraneous influences, such as snow loads. In addition, loosening of the screw 40 during the operation of the solar module 10 is prevented.

In all four embodiment examples the body 26 is arranged in a passing area 36. The center of this passing area 36 may correspond with the longitudinal axis A of the body 26. According to the method used, the pane 16 of glass is only heated in the passing area 36 and the body 26 is guided or passed through the pane 16 of glass in this passing area 36.

The invention has been described in an exemplary way by the use of preferable embodiment examples. Modifications or variations, for ex ample with respect to the design of the solar module or the body, which are apparent from the description for a person skilled in the art do not depart from the idea of the present invention and thus are within the scope of the present invention which is defined by the appended claims.

### PARTS LIST

10 solar module
12 solar cell
14 encapsulation
16 pane of glass
18 first glass face
20 second glass face
22 layer of embedment material
24, 24′, 24″ electrical conductor
26′, 26″, 26′″, 26″″ body
28 inner end
30 outer end
32 head
34 through-hole
36 passing area
38 thread
40 screw
42 further encapsulation
A axis
T₁ first temperature
T₂ second temperature
T₃ third temperature
T_{K1} first body temperature
T_{K2} second body temperature
T_{K3} third body temperature

While the invention has been illustrated and described as embodied in a solar module containing an encapsulated solar cell and a method of providing an electrical connection through the encapsulation to deliver electrical energy from the solar cell, it is not intended to be limited to the details shown, since various modifications and changes may be made without departing in any way from the spirit of the present invention.

Without further analysis, the foregoing will so fully reveal the gist of the present invention that others can, by applying current knowledge, readily adapt it for various applications without omitting features that, from the standpoint of prior art, fairly constitute essential characteristics of the generic or specific aspects of this invention.

What is claimed is new and is set forth in the following appended claims.

We claim:

1. A solar module for converting radiation energy, in particular sunlight, into electrical energy, said solar module comprising
a solar cell (12) for converting radiation energy into electrical energy;
an electrical conductor (24) for conducting the electrical energy;
an encapsulation (14) encasing the solar cell (12) to protect the solar cell (12), said encapsulation (14) comprising one or more panes of glass to protect and stabilize the solar cell (12) and a layer (22) of embedment material into which the solar cell (12) is laminated or cast; and
a body (26) fused into the one or more panes (16) of glass for conducting the electrical energy through the one or more panes (16) of glass or for passing an electrical conductor (24) through the one or more panes (16) of glass.

2. The solar module according to claim 1, wherein the body (26) is configured as an electrically conducting pin conductively connected with the electrical conductor (24).

3. The solar module according to claim 2, wherein said electrically conducting pin is a cylindrical pin, a tapered dowel pin, or a bolt with a head (32).

4. The solar module according to claim 1, wherein the body (26) is pro vided with a through-hole (34) for passing the electrical conductor (24) through the body (26) and through the one or more panes (16) of glass.

5. The solar module according to claim 1, wherein the body (26) comprises a thread (38) into which a screw (40) can be screwed in order to connect the electrical conductor (24) with the body (26) in an electrically conductive way.

6. The solar module according to claim 5, further comprising an additional encapsulation (42) to protect the electrical conductor (24) and to secure the screw (40).

7. The solar module according to claim 1, wherein the body (26) consists of a non-conducting material and is provided with a through-hole (34) for passing the electrical conductor (24) through the body (26) and through the pane (16) of glass.

8. A method for fusing a body (26) into one or more panes (16) of glass (16) of a solar module (10) according to claim 1, in which the body (26) serves for conducting the electrical energy through the one or more panes (16) of glass, said method comprising the steps of:
a) heating the one or more panes (16) of glass from a first temperature (T₁) to a second temperature (T₂), wherein the second temperature (T₂) is equal to or higher than the glass transition temperature of said glass in said one or more panes;
b) passing the body (26) through the one or more panes (16) of glass at the second temperature (T₂); and
c) cooling the one or more panes (16) of glass (16) to a third temperature (T₃).

9. The method according to claim 8, wherein the one or more panes (16) of glass are heated in a passing area (36) in which the body (26) is passed through the one or more panes (16) of glass.

10. The method according to claim 8, wherein the one or more panes (16) of glass have a first glass face (18) and a second glass face (20) arranged opposite from the first glass face (18), said method further comprising heating said first glass face (18) and said second glass face (20).

11. The method according to claim 8, wherein the one or more panes (16) of glass are subjected to a forced cooling from the second temperature (T₂) to the third temperature (T₃).

12. The method according to claim 8, further comprising the additional steps of:
a′) heating the body (26) from a first body temperature (T_{K1}) to a second body temperature (T_{K2});
b′) passing the body (26) at the second body temperature (T_{K2}) through the one or more panes (16) of glass (16) at the second temperature (T₂); and
c′) cooling the body (26) from the second body temperature (T_{K2}) to a third body temperature (T_{K3}).

13. The method according to claim 12, wherein the second body temperature (T_{K2}) is higher than the second temperature (T₂) of the one or more panes (16) of glass.

14. The method according to claim 12, wherein the body (26) is subjected to a forced cooling from the second body temperature (T_{K2}) to the third body temperature (T_{K3}).
